(19) United States
(12) Patent Application Publication
(10) Pub. No.: US 2015/0311920 A1
(43) Pub. Date: Oct. 29, 2015

(54) DECODER FOR A MEMORY DEVICE, MEMORY DEVICE AND METHOD OF DECODING A MEMORY DEVICE

(71) Applicant: Agency for Science, Technology and Research, Singapore (SG)

(72) Inventor: Xueqiang Wang, Singapore (SG)

(21) Appl. No.: 14/691,732

(22) Filed: Apr. 21, 2015

(30) Foreign Application Priority Data
Apr. 25, 2014 (SG) 10201401824Q

(51) Int. Cl. H03M 13/15; H03M 13/00; G06F 11/10

(52) U.S. Cl. CPC H03M 13/1555; G06F 11/1008; H03M 13/616; H03M 13/1545

(57) ABSTRACT

According to embodiments of the present invention, a decoder for a memory device is provided. The decoder includes an error detection circuitry configured to multiply a vector of one or more data words with a parity matrix to determine a plurality of syndrome values and generate a plurality of coefficients from multiplying a syndrome vector with an inverse of a syndrome matrix; and an error correction circuitry configured to perform a Chien search on a first part of the plurality of coefficients to determine error indicators indicating error locations in a first part of the one or more data words, and subsequently on a second part of the plurality of coefficients to determine error indicators indicating error locations in a second part of the one or more data words. According to further embodiments of the present invention, a memory device and method of decoding a memory device are also provided.

### CROSS-REFERENCE TO RELATED APPLICATION

This application claims the benefit of priority of Singapore patent application No. 10201401824Q, filed 25 Apr. 2014, the content of it being hereby incorporated by reference in its entirety for all purposes.

### TECHNICAL FIELD

Various embodiments relate to a decoder for a memory device, a memory device and a method of decoding a memory device.

### BACKGROUND

Emerging non-volatile memory (NVM) devices, including phase change memory (PCM), spin transfer torque magnetoresistive random-access memory (STT-MRAM), resistive random-access memory (ReRAM) and so on, are desired in various applications where high data quality is required. For example, NVM may be used for code storage in handphones and automotive applications, and for data cache in data centres.

However, emerging NVM devices may suffer from data errors for various reasons. NVM may suffer from process variation issues as memory process scales down aggressively. Moreover, each type NVM may have its specific reliability challenges. For example, PCM may have a problem of resistance drift and the drift-induced errors may be imminent over time, therefore multiple bit errors may be expected to be significantly common. STT-MRAM may have intrinsic asymmetry magnetic tunneling junction (MTJ) switching so the write error rate may be much larger for writing bit ‘1’ than that for writing bit ‘0’.

Reliability challenges at device level may be improved at system level by using signal processing and error correction code (ECC) techniques. ECC is commonly employed in semiconductor memory devices. ECC system generally includes encoding and decoding. Encoding is to encode the original data by adding some parity bits and write the codeword to memory cells. Decoding is to find out the errors from the retrieved data read from memory and recover the data stored in memory cells.

Conventionally, Hamming code, a type of ECC with single-error correction and double-error detection (SEC-DED), may be applied in memory devices. However, as memory device has smaller cell size and higher density, stability issues due to process variation may worsen, leading to higher bit error rate. Consequently, a stronger or more effective ECC capable of correcting multiple errors may be or may become indispensable in memory devices.

In addition, emerging NVMs are high-speed memory, so ECC decoder may be expected to have minimum memory access latency overhead. Small decoder area may also be desirable since memory may be significantly sensitive to cost.

Bose-Chaudhuri-Hocquenghem (BCH) code is a powerful ECC technique that is able to correct multiple random errors. BCH code is based on the Galois field (GF) theory and thereby has an algebraic decoding algorithm. BCH code is considerably popular in communication systems, digital video systems, and solid state drives. Generally, BCH decoding may include three pipeline stages, namely, (i) to calculate syndrome vectors from received data; (ii) to determine of error locator polynomial (ELP) from the syndromes; and (iii) to perform Chien search with the ELP to identify error locations. BCH decoding may conventionally be a serial process, involving serial implementation using a number of clock cycles to complete the three stages where the first and third stages may be realized with linear feedback register structure and the second stage may be implemented with an iterative algorithm. Large amount of errors (e.g., error correction capability, t>5) may require the serial implementation of BCH decoding. However, such slow BCH decoding may hardly be applied in high-speed memory devices with access time in the order of tens of nanoseconds, and instead may be used in, e.g., communication and digital television system.

Some techniques for comparatively faster decoding have been developed. For example, a pre-defined look-up table may be employed where syndromes may be used to index the table and each indexed row may directly provide locations of erroneous bits. However, this exemplary technique may usually be limited to double-error correction (DEC) BCH code because the table size may grow excessively large as the number of errors to be corrected increases.

An alternative technique may be to design a full-parallel BCH decoder which may be implemented totally with combinational logic circuitry. Such a parallel implementation may be realized without performing any iteration. However, a shortcoming of this technique may be that in order to achieve low latency, the area of the bit-parallel decoder may be significantly large. This may also affect the length of codeword which is linearly proportional to the area. As such, small amount of errors (e.g., error correction capability, t<5) may be handled by this parallel implementation of BCH decoding, which may be used in optical and memory systems.

FIG. 1 shows a function block diagram 101 illustrating a read path with an error correction mechanism in a conventional memory device. As shown in FIG. 1, the read path 100 includes a memory array 102, a sense amplifier circuitry 104, an error detection and correction circuitry 106, a data register circuitry 108, an output control circuitry 110, an address control circuitry 112, and an input/output (I/O) pad 114. The memory array 102 may be a two-dimensional array of rows called wordline (WL) 103 and columns called bitline (BL) 105, and may include a row decoder 107. Each memory cell in the array may be coupled to a specific WL 103 and BL 105 that may constitute a specific cell address. All memory cells in the same WL 103 may be referred to as a page. During a memory read operation, the address control circuitry 112 may receive an address from a read command and may decode the address into according row address 109 and column address 111. With the row decoder 107 or interchangeably referred to as a row address decoder, one WL 103 in the memory array 102 may be selected and a page of data (e.g., 32 bytes/64 bytes page size) may be read out of the memory array 102 in parallel. Then, the sense amplifier circuitry 104 may compare analog signals (e.g., current or voltage) from the memory cells with a pre-set reference, make a decision and generate according digital binary signals. To address the issues of defective memory cell or incorrect sensing, the error detection and correction circuitry 106 may be employed to correct bit errors in the data and send the valid word to the data register circuitry 108. A memory device may have limited data I/O pins, which may typically be with ×8/×16/×32 data interface. Hence, data may have to be output in a serial manner based on 1 byte/2 bytes I/O pin-size. With the column address 111, the output control circuitry 110 may select the according data from the data register 108, and output the according data to the I/O pad 114. It may be seen that in the memory device, the data may be read from the memory array 102 with parallel page-size data and subsequently sent to the I/O pad 114 serially. Hence, there may be an intrinsic parallel-to-serial conversion along the read path 100. This may be a unique feature of the memory device.

FIG. 2A shows a block diagram 201 of a conventional BCH decoder 200. The BCH decoder 200 may be described in similar context to the error detection and correction circuitry 106 of FIG. 1. FIG. 2B shows a block diagram 220 illustrating a read path (e.g., as in FIG. 1) with the BCH decoder 200 in a memory device 222.

In other words, the whole decoder 200 is inserted into the read path with full-parallel implementation as shown in FIG. 2B.

A BCH code may be a widely used ECC code that is developed on the theory of Galois field (GF) and is able to correct multiple-bit random errors. The BCH code may be characterized by the following parameters: codeword length n, information data length k, error correction capability t, and degree of GF m, in which n=2^{m}−1 and n−k≧mt. A BCH ECC system may include a BCH encoder and a BCH decoder. BCH encoding may be used to encode a k-bit information data into a n-bit codeword with a generator polynomial. Information data vector may be denoted as uₖ₋₁, uₖ₋₂, . . . u₀ and a codeword vector may be denoted as vₙ₋₁, vₙ₋₂, . . . v₀. The according polynomial form may be represented as u(x)=uₖ₋₁x^{k-1}+uₖ₋₂x^{k-2} . . . +u₀ and v(x)=vₙ₋₁xⁿ⁻¹+vₙ₋₂xⁿ⁻² . . . +v₀, respectively. The generator polynomial may be obtained over GF(2^{m}) and represented as g(x)=gₙ₋ₖx^{n-k}+gₙ₋ₖx^{n-k-1} . . . +g₀.

For a given BCH(n, k, t) code, the relationship between u(x), g(x), and v(x) may be given by the following equation:

v(x)=u(x)x^{n-k}+(u(x)x^{n-k})mod g(x) Equation [1]

In memory devices, data encoding may occur during memory write operation. After encoding, a codeword may be written into one page in the memory array.

A typical BCH decoder 200 may include main three modules, namely, a syndrome generator 202, an ELP solver 204, and a Chien search module (or interchangeably referred to as a Chien search circuitry) 206. As shown in FIG. 2A, a received data or codeword 203 from the memory array (e.g., the memory array 102 of FIG. 1) may be first provided to the syndrome generator 202 in the BCH decoder 200. The received data 203 may be denoted as rₙ₋₁, rₙ₋₂ . . . r₀ and its according polynomial form may be denoted as r(x)=rₙ₋₁xⁿ⁻¹+rₙ₋₂xⁿ⁻²+ . . . +r₀. The received data 203 may contain error bits if some memory cells are defective or the sense amplifier circuitry (e.g., the sense amplifier circuitry 104 of FIG. 1) makes an incorrect decision. Therefore, r(x) may be represented as shown in Equation [2]:

r(x)=v(x)+e(x) Equation [2]

where v(x) is the valid BCH codeword and e(x) indicates the errors in the received vector.

Equation [2] may be performed by a summing circuit 208.

Syndromes may be computed from the received vector using a method to perform a modulo division of r(x) by the minimal polynomial over GF(2^{m}) as shown in Equation [3]:

Sᵢ=r(x)mod ψᵢ(x) i=1,3,5 . . . 2t−1 Equation [3]

where ψⱼ(x) is the minimal polynomial of element αⁱ over GF(2^{m}).

For binary BCH code, only the odd-index syndromes may need to be computed using the above Equation [3] because the even-index syndromes may be obtained using the following property:

S₂ᵢ=(sᵢ)² i=1 . . . t Equation [4]

The syndrome values may indicate whether there are errors in the received data. For example, if all the syndromes are zero, it may be indicated that the received data is a valid codeword and no error exists. Otherwise, if any one syndrome is non-zero, at least one error exists.

The modulus operation in Equation [3] may be typically implemented with a linear feedback shift register (LFSR) structure. The received data may be sent into the LFSR circuit serially. At each clock cycle, the new input received data may be added with the output of the register to produce an intermediate syndrome vector in the registers. The process may be repeated until all the received data are sent into the LFSR, then each bit stored in the registers may be associated with an element in the syndrome vector.

The calculated syndromes may be sent to the ELP solver 204 to determine the coefficients of error-location polynomial as shown in the following:

σ(x)=σ₀+σ₁x+σ₂x² . . . +σₜx^{t} Equation [5]

After the error-location polynomial is determined, the Chien search module 206 may be employed to find out the error locations and correct the errors. The Chien search, named after R. T. Chien, is a search algorithm for determining roots of error locator polynomials (or error-location polynomials) over a Galois field.

Now turning back to FIG. 1, when ECC is applied in memory devices, the error detection and correction circuitry 106 may inserted between the sense amplifier circuitry 104 and the data register circuitry 108. In order to achieve fast memory read access, minimum decoding latency of the ECC decoder may be required. Conventionally, Hamming code may be applied due to its significantly short decoding latency and small area. However, Hamming code may correct only single bit error, which may render it insufficient with the increase of memory cell bit error rate. Hence, BCH code may be applied in memory devices.

A BCH decoder may usually be implemented with the LFSR structure and an iterative Berlekamp-Massey (BM) algorithm for obtaining the coefficients of error-location polynomial. The BM algorithm is an iterative algorithm which first initializes the coefficients to syndrome values, then computes a discrepancy of current and previous iterations and updates the coefficients in the next iteration according to the discrepancy values. Iterations may be repeated for t times to obtain the final results. Generally, BM algorithm may be implemented with sequential logic circuitry, taking t clock cycles to complete iterations. This iterative algorithm may be suitable for large number of correctable errors t (t>5).

According the above description of the BCH decoding process, the conventional BCH decoder may hardly apply in high-speed memory devices, which may significantly degrade read performance. Although the BCH decoder realized totally with combinational logic may be proposed, it may be limited to double error correction (DEC) BCH code or may have an excessively large area due to bit-parallel Chien search.

Therefore, there is a need to provide an apparatus of a BCH decoder or an improved BCH decoder in memory devices that aims to achieve significantly short (minimum) decoding latency so as to satisfy fast memory read access, as well as minimizes the concomitant increase of gate count so as to save cost of silicon area of semiconductor memory devices, and effectively reduce overall chip cost, thereby addressing at least the problems above.

### SUMMARY

According to an embodiment, a decoder for a memory device is provided. The decoder may include an error detection circuitry configured to multiply a vector of one or more data words for which an error detection is to be carried out with a parity matrix to determine a plurality of syndrome values and generate a plurality of coefficients from multiplying a syndrome vector with an inverse of a syndrome matrix, wherein both the syndrome vector and the syndrome matrix include the plurality of syndrome values; and an error correction circuitry configured to perform a Chien search on a first part of the plurality of coefficients to determine a first set of error indicators indicating error locations in a first part of the one or more data words, and subsequently perform a Chien search on a second part of the plurality of coefficients to determine a second set of error indicators indicating error locations in a second part of the one or more data words.

According to an embodiment, a memory device is provided. The memory device may include a sense amplifier circuitry configured to provide one or more data words; a decoder including: an error detection circuitry configured to multiply a vector of the one or more data words for which an error detection is to be carried out with a parity matrix to determine a plurality of syndrome values and generate a plurality of coefficients from multiplying a syndrome vector with an inverse of a syndrome matrix, wherein both the syndrome vector and the syndrome matrix include the plurality of syndrome values; and an error correction circuitry configured to perform a Chien search on a first part of the plurality of coefficients to determine a first set of error indicators indicating error locations in a first part of the one or more data words, and subsequently perform a Chien search on a second part of the plurality of coefficients to determine a second set of error indicators indicating error locations in a second part of the one or more data words; and a data register configured to store the one or more data words and the plurality of coefficients, wherein the error detection circuitry is arranged between the sense amplifier circuitry and the data register.

According to an embodiment, a method of decoding a memory device is provided. The method may include multiplying a vector of one or more data words for which an error detection is to be carried out with a parity matrix to determine a plurality of syndrome values; generating a plurality of coefficients from multiplying a syndrome vector with an inverse of a syndrome matrix, wherein both the syndrome vector and the syndrome matrix include the plurality of syndrome values; performing a Chien search on a first part of the plurality of coefficients to determine a first set of error indicators indicating error locations in a first part of the one or more data words; and subsequently performing a Chien search on a second part of the plurality of coefficients to determine a second set of error indicators indicating error locations in a second part of the one or more data words.

### BRIEF DESCRIPTION OF THE DRAWINGS

In the drawings, like reference characters generally refer to like parts throughout the different views. The drawings are not necessarily to scale, emphasis instead generally being placed upon illustrating the principles of the invention. In the following description, various embodiments of the invention are described with reference to the following drawings, in which:

FIG. 1 shows a function block diagram of a conventional memory device.

FIG. 2A shows a block diagram of a conventional Bose-Chaudhuri-Hocquenghem (BCH) decoder.

FIG. 2B shows a block diagram illustrating a read path with the BCH decoder of FIG. 2A in a conventional memory device.

FIG. 3A shows a schematic view of a decoder for a memory device, according to various embodiments.

FIG. 3B shows a schematic view of a memory device, according to various embodiments.

FIG. 3C shows a flow chart illustrating a method of decoding a memory device, according to various embodiments.

FIG. 4 shows a schematic view of a BCH decoder in a memory device, in accordance with various embodiments.

FIG. 5 shows a schematic view of a syndrome generator circuitry, in accordance with various embodiments.

FIG. 6 shows a schematic view of an error locator polynomial (ELP) solver circuitry, in accordance with various embodiments.

FIG. 7 shows a schematic view of an error correction circuitry, in accordance with various embodiments.

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Embodiments described in the context of one of the methods or devices are analogously valid for the other methods or devices. Similarly, embodiments described in the context of a method are analogously valid for a device, and vice versa.

Features that are described in the context of an embodiment may correspondingly be applicable to the same or similar features in the other embodiments. Features that are described in the context of an embodiment may correspondingly be applicable to the other embodiments, even if not explicitly described in these other embodiments. Furthermore, additions and/or combinations and/or alternatives as described for a feature in the context of an embodiment may correspondingly be applicable to the same or similar feature in the other embodiments.

In the context of various embodiments, the articles “a”, “an” and “the” as used with regard to a feature or element include a reference to one or more of the features or elements.

In the context of various embodiments, the phrase “at least substantially” may include “exactly” and a reasonable variance.

In the context of various embodiments, the term “about” or “approximately” as applied to a numeric value encompasses the exact value and a reasonable variance.

As used herein, the term “and/or” includes any and all combinations of one or more of the associated listed items.

As used herein, the phrase of the form of “at least one of A or B” may include A or B or both A and B. Correspondingly, the phrase of the form of “at least one of A or B or C”, or including further listed items, may include any and all combinations of one or more of the associated listed items.

Various embodiments may provide a low-latency and area-efficient Bose-Chaudhuri-Hocquenghem (BCH) decoder for a non-volatile memory (NVM).

Various embodiments may relate to the field of data error correction in memory devices, and more particularly relates to binary BCH code decoder implementation in memory devices.

Various embodiments may provide a hardware decoder of binary BCH code for a memory device that provides significantly fast decoding speed and relatively low complexity. A BCH decoder architecture may be designed by exploring the unique feature of data flow conversion in a memory read path. The BCH decoder may include two portions, namely, the error detection circuitry and the error correction circuitry. Each portion may be located among a corresponding data path in memory, and may be designed with a specific circuit structure.

The error detection circuitry may include a syndrome generator and an error location polynomial module. The error detection circuitry may be located among a parallel data path between a sense amplifier and a data register in the memory. The error detection circuitry may be totally implemented with combinational logic in a full-parallel manner in order to minimize memory access latency overhead. The error correction circuitry may include an index control circuitry and a Chien search circuitry. The error correction circuitry may be located among a serial data path between the data register and an I/O interface in the memory. The error correction circuitry may be directed towards small area solution in which the Chien search module may be configured as the start search index may be controlled by a memory column address and the number of bits processed per clock cycle may be determined by the I/O port number of the memory device. In other words, the architecture may enable the BCH decoder in accordance with various embodiments to reduce memory access latency as well as silicon area.

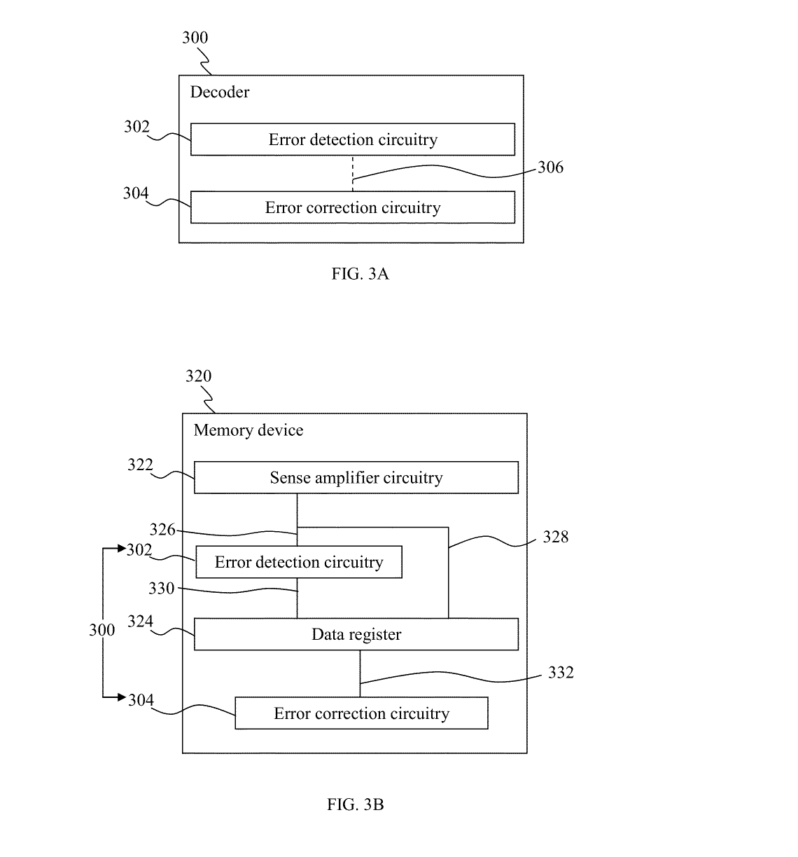

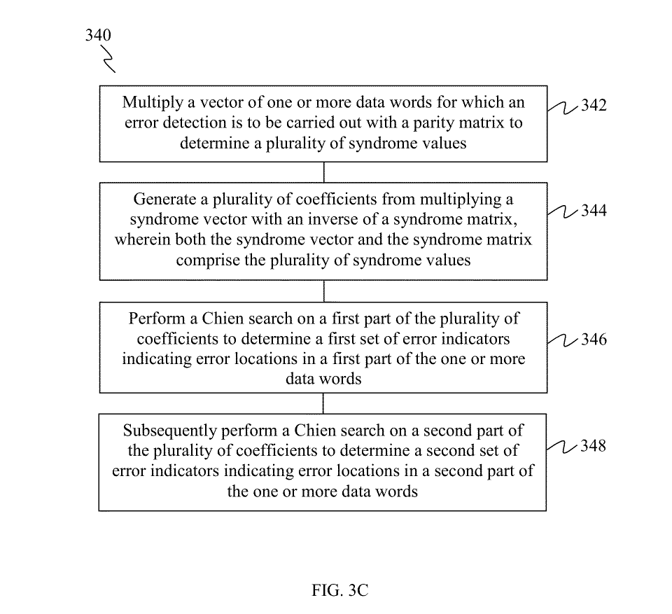

FIG. 3A shows a schematic view of a decoder 300 for a memory device, according to various embodiments. The decoder 300 includes an error detection circuitry 302 configured to multiply a vector of one or more data words for which an error detection is to be carried out with a parity matrix to determine a plurality of syndrome values and generate a plurality of coefficients from multiplying a syndrome vector with an inverse of a syndrome matrix, wherein both the syndrome vector and the syndrome matrix include the plurality of syndrome values; and an error correction circuitry 304 configured to perform a Chien search on a first part of the plurality of coefficients to determine a first set of error indicators indicating error locations in a first part of the one or more data words, and subsequently perform a Chien search on a second part of the plurality of coefficients to determine a second set of error indicators indicating error locations in a second part of the one or more data words. The error detection circuitry 302 and the error correction circuitry 304 are in communication with each other, as denoted by a dotted line 306 which may represent indirect electrical coupling, or indirect physical coupling between the error detection circuitry 302 and the error correction circuitry 304.

In the context of various embodiments, the plurality of syndrome values may indicate a presence of at least one error in the one or more data words, while the plurality of coefficients may indicate the number of errors in the one or more data words. Further, the first set of error indicators may include at least one error indicator indicating at least one error location in the first part of the one or more data words, while the second set of error indicators may include at least one error indicator indicating at least one error location in the second part of the one or more data words. The one or more data words may include a page of read out of a memory array of the memory device in parallel. The one or more data words may be of a 32-byte page size or a 64-byte page size. The first part of the one or more data words may be distinct from the second part of the one or more data words. As such, the first part and the second part of the one or more data words may not overlap each other.

In other words, the error detection circuitry 302 may be configured to parallely process one or more data words to determine the plurality of syndrome values and the plurality of coefficients. “Parallely process” with respect to the one or more data words means to carry out an operation on the one or more data words in its entirety, i.e., on all bits of the one or more data words at at least substantially the same time (e.g., in a parallel manner). The error correction circuitry 304 may be configured to first process one part (e.g., the first part) of the plurality of the coefficients to locate at least one error in the first part of the one or more data words. Once completed, the error correction circuitry 304 may be configured to then process a subsequent part (e.g., the second part) of the plurality of the coefficients to locate at least one error in a subsequent part of the one or more data words. The error correction circuitry 304 may be configured to continue processing further parts of plurality of the coefficients to locate at least one error in each of the further parts of the one or more data words in a similar manner, thereby in effect, serially (sequentially) performing a Chien search on the plurality of the coefficients.

In various embodiments, the error detection circuitry 302 may be arranged along a parallel memory read path of the memory device.

In various embodiments, the error detection circuitry 302 may include a syndrome generator configured to multiply the vector of one or more data words with the parity matrix including elements of a Galois Field to determine the plurality of syndrome values including odd-index syndrome values.

In other words, the parity matrix may include elements of a Galois Field where Galois Fields are expressed as power of a, a being the primitive element over GF(2^{m}), and the plurality of syndrome values may include odd-index syndrome values, e.g., S₁, S₃, S₅, and so on.

In various embodiments, the syndrome generator may further be configured to determine even-index syndrome values S₂ᵢ based on the odd-index syndrome values S₂ᵢ₋₁ and a property of S₂ᵢ=(sᵢ)² where i=1, . . . t, and t being an error correction capability of the decoder 300. The error correction capability may be an integer value. For example, the error correction capability may be less than or equal to 5.

In various embodiments, the syndrome generator may include a plurality of logic trees, each of the plurality of logic trees configured to receive and process each data word of the one or more data words to generate the plurality of syndrome values at at least substantially the same time.

In the context of various embodiments, the phrase “at least substantially the same time” may mean at least substantially simultaneously.

The logic tree as described herein may include a logic XOR tree. To form an XOR-tree circuit structure, each of the plurality of logic XOR trees may include a combinational arrangement of XOR logic gates and may perform modulo-2 addition of each data word of the vector of one or more data words.

In various embodiments, the syndrome vector may include the plurality of syndrome values or at least part of the plurality of syndrome values. The syndrome matrix may include the plurality of syndrome values or at least part of the plurality of syndrome values.

In various embodiments, the error detection circuitry 302 may further include an error locator polynomial (ELP) solver configured to generate the plurality of coefficients from multiplying the syndrome vector with the inverse of the syndrome matrix, wherein the syndrome vector may further include the even-index syndrome values of S₂ᵢ where i=1, . . . t; and wherein the syndrome matrix may further include the even-index syndrome values of S₂ᵢ where i=1, . . . t—1.

It should be appreciated that the syndrome vector is different from the syndrome matrix.

For example, the syndrome vector may include a column vector having a size of A×1, and the syndrome matrix may be an A×A matrix. In this example, for the plurality of coefficients of

$$[ \begin{matrix}{σ}_{t} \\ {σ}_{t - 1} \\ ⋮ \\ {σ}_{1}\end{matrix} ] ,$$

the elements in the syndrome vector may be arranged starting from Sₜ₊₁ to S₂ₜ in a consecutive order, e.g., the syndrome vector may be

$$[ \begin{matrix}{S}_{t + 1} \\ {S}_{t + 2} \\ ⋮ \\ {S}_{2 t}\end{matrix} ] ,$$

and the syndrome matrix may be

$$[ \begin{matrix}{S}_{1} & {S}_{2} & … & {S}_{t} \\ {S}_{2} & {S}_{3} & … & {S}_{t + 1} \\ ⋮ & ⋮ & … & ⋮ \\ {S}_{t} & {S}_{t + 1} & … & {S}_{2 t + 1}\end{matrix} ] .$$

The relationship between the syndrome values and the plurality of coefficients may be based on Newton's identities. It should be appreciated that the syndrome vector and the syndrome matrix may take different forms or arrangements.

In another non-limiting example, for the plurality of coefficients of

$$[ \begin{matrix}{σ}_{1} \\ {σ}_{2} \\ {σ}_{3} \\ {σ}_{4} \\ ⋮ \\ {σ}_{t - 1} \\ {σ}_{t}\end{matrix} ] ,$$

the syndrome vector may take a form of

$$[ \begin{matrix}- {S}_{1} \\ - {S}_{3} \\ - {S}_{5} \\ - {S}_{7} \\ ⋮ \\ - {S}_{2 t - 3} \\ - {S}_{2 t - 1}\end{matrix} ]$$

and the syndrome matrix may take a form of

$$[ \begin{matrix}1 & 0 & 0 & 0 & … & 0 & 0 \\ {S}_{2} & {S}_{1} & 1 & 0 & … & 0 & 0 \\ {S}_{4} & {S}_{3} & {S}_{2} & {S}_{1} & … & 0 & 0 \\ {S}_{6} & {S}_{5} & {S}_{4} & {S}_{3} & … & 0 & 0 \\ ⋮ & ⋮ & ⋮ & ⋮ & ⋱ & ⋮ & ⋮ \\ {S}_{2 t - 4} & {S}_{2 t - 5} & {S}_{2 t - 6} & {S}_{2 t - 7} & … & {S}_{t - 2} & {S}_{t - 3} \\ {S}_{2 t - 2} & {S}_{2 t - 3} & {S}_{2 t - 4} & {S}_{2 t - 5} & … & {S}_{t} & {S}_{t - 1}\end{matrix} ] .$$

Regardless of the forms or arrangements the syndrome vector and syndrome matrix may take, the plurality of coefficients determined in each situation (or each formulation) would result in the same respective values.

In other embodiments, the error detection circuitry 302 may further include an error locator polynomial (ELP) solver configured to generate the plurality of coefficients by applying a Peterson-Gorenstein-Zierler (PGZ) algorithm on the plurality of syndrome values. The ELP solver may include a plurality of square circuits, each configured to determine a square syndrome value for each of the plurality of syndrome values; and a plurality of process elements configured to generate the plurality of coefficients based on the square syndrome values and the plurality of syndrome values.

For example, each of the plurality of square circuits may include a summing circuit configured to perform an addition of selected syndrome values of the plurality of syndrome values. Further, each of the plurality of process elements may include a combination of XOR logic gates and AND logic gates.

The PGZ algorithm will be described in more details below in relation to Equation [7].

In various embodiments, the error correction circuitry 304 may be arranged along a serial memory read path of the memory device.

In various embodiments, the error correction circuitry 304 may include an index control circuitry configured to receive a column address of the one or more data words to determine a starting search index. The index control circuitry may include a plurality of look-up tables (LUTs) configured to convert the column address to the starting search index.

In various embodiments, the error correction circuitry 304 may further include a Chien search module configured to select from the plurality of coefficients based on the starting search index, the first part of the plurality of coefficients, and to perform the Chien search on the first part of the plurality of coefficients.

In various embodiments, the Chien search module may be configured to determine the first set of error indicators based on roots of an error locator polynomial, wherein the error locator polynomial includes the first part of the plurality of coefficients.

In various embodiments, the Chien search module may further be configured to select from the plurality of coefficients based on the starting search index, the second part of the plurality of coefficients, and to perform the Chien search on the second part of the plurality of coefficients.

In various embodiments, the Chien search module may be configured to determine the second set of error indicators based on roots of an error locator polynomial, wherein the error locator polynomial includes the second part of the plurality of coefficients.

In a Chien search, error is determined to be at a location index i if it has been determined that α⁻ⁱ is a root of the error locator polynomial where α is a primitive element over a Galois field. The Chien search module may have a degree of parallelism determined by the number of input-output (I/O) ports of the memory device. The degree of parallelism may refer to the number of bits processed at each clock cycle by the Chien search module. In various embodiments, the Chien search module may have a degree of parallelism equal to or double the number of input-output (I/O) ports of the memory device. For example, the degree of parallelism may be in a range of 8 bits to 64 bits. A Chien search algorithm will be described in more details below in relation to Equation [8].

In various embodiments, the Chien search module may include a plurality of multipliers configured to multiple the starting search index with the first part of the plurality of coefficients or the second part of the plurality of coefficients.

The Chien search module may further include a plurality of registers configured to store a plurality of multiplication results of the starting search index and the first part of the plurality of coefficients, or a plurality of multiplication results of the starting search index and the second part of the plurality of coefficients.

In context of various embodiments, the term “store” in relation to the plurality of registers in the Chien search module may mean to temporarily store for a subsequent cycle of operation. In other words, the plurality of registers may store the multiplication results for a next cycle of operation.

In various embodiments, the decoder 300 may include a Bose-Chaudhuri-Hocquenghem (BCH) decoder.

A memory device including a decoder according to various embodiments (e.g., the decoder 300 of FIG. 3A) may be provided.

FIG. 3B shows a schematic view of a memory device 320, according to various embodiments. The memory device 320 includes a sense amplifier circuitry 322 configured to provide one or more data words; a decoder 300 including: an error detection circuitry 302 configured to multiply a vector of the one or more data words for which an error detection is to be carried out with a parity matrix to determine a plurality of syndrome values and generate a plurality of coefficients from multiplying a syndrome vector with an inverse of a syndrome matrix, wherein both the syndrome vector and the syndrome matrix include the plurality of syndrome values; and an error correction circuitry 304 configured to perform a Chien search on a first part of the plurality of coefficients to determine a first set of error indicators indicating error locations in a first part of the one or more data words, and subsequently perform a Chien search on a second part of the plurality of coefficients to determine a second set of error indicators indicating error locations in a second part of the one or more data words; and a data register 324 configured to store the one or more data words and the plurality of coefficients. The error detection circuitry 302 may be arranged between the sense amplifier circuitry 322 and the data register 324.

The sense amplifier circuitry 322, the error detection circuitry 302 and the data register 324 are in communication with one another, as denoted by a line 326 which may represent electrical coupling, or physical coupling between the sense amplifier circuitry 322 and the error detection circuitry 302, a line 328 which may represent electrical coupling, or physical coupling between the sense amplifier circuitry 322 and the data register 324, and a line 330 which may represent electrical coupling, or physical coupling between the error detection circuitry 302 and the data register 324. The data register 324 and the error correction circuitry 304 are in communication with each other, as denoted by a line 332 which may represent electrical coupling, or physical coupling between the data register 324 and the error correction circuitry 304.

The decoder 300 of FIG. 3B may include the same or like elements or components as those of the decoder 300 of FIG. 3A, and as such, the same numerals are assigned and the like elements may be as described in the context of the decoder 300 of FIG. 3A, and therefore the corresponding descriptions are omitted here.

In the context of various embodiments, the one or more data words to be stored in the data register 324 may be referred to as information bits.

In various embodiments, the memory device 320 may further include an input-output (I/O) interface configured to receive or output data into or from the memory device 320, wherein the error correction circuitry 304 may be arranged between the data register 324 and the I/O interface (not shown in FIG. 3B).

In various embodiments, the memory device 320 may further include an array of memory cells, wherein the sense amplifier circuitry 322 may be further configured to receive signals from the memory cells to generate the one or more data words. For example, the array of memory cells may include a two dimensional array of rows (wordline) and columns (bitline).

The memory device 320 may further include an address control circuitry configured to provide a row address and a column address. The memory device 320 may further include a row decoder configured to receive the row address to activate a wordline of the array of memory cells. The one or more data words may include a page of data based on the row address.

In various embodiments, the error correction circuitry 304 may be configured to receive the first part of the plurality of coefficients or the second part of the plurality of coefficients based on the column address.

The memory device 320 may further include an output control circuitry configured to select the first part of the one or more data words or the second part of the one or more data words based on the column address.

In other words, the error correction circuitry 304 may operate synchronously with the output control circuitry such that the first set of error indicators generated from the error correction circuitry 304 corresponds to the first part of the one or more data words to be corrected, and the second set of error indicators generated from the error correction circuitry corresponds to the second part of the one or more data words to be corrected.

In various embodiments, the memory device 320 may further include an addition module configured to remove at least one error from the first part of the one or more data words based on the first set of error indicators, or from the second part of the one or more data words based on the second set of error indicators.

In various embodiments, the memory device 320 may include a non-volatile memory device. For example, the memory device 320 may include a phase change memory (PCM), a spin transfer torque magnetoresistive random-access memory (STT-MRAM), or a resistive random-access memory (ReRAM).

FIG. 3C shows a flow chart 340 illustrating a method of decoding a memory device, according to various embodiments.

The memory device may be described in similar context to the memory device 320 of FIG. 3B. It should therefore be appreciated that descriptions in the context of the memory device 320 and/or the decoder 300 may correspondingly be applicable in relation to the method for decoding a memory device.

In FIG. 3C, at 324, a vector of one or more data words for which an error detection is to be carried out is multiplied with a parity matrix to determine a plurality of syndrome values. At 344, a plurality of coefficients is generated from multiplying a syndrome vector with an inverse of a syndrome matrix, wherein both the syndrome vector and the syndrome matrix include the plurality of syndrome values. At 346, a Chien search is performed on a first part of the plurality of coefficients to determine a first set of error indicators indicating error locations in a first part of the one or more data words. At 348, a Chien search is subsequently performed on a second part of the plurality of coefficients to determine a second set of error indicators indicating error locations in a second part of the one or more data words.

In various embodiments, multiplying the vector of one or more data words with the parity matrix to determine the plurality of syndrome values at 342 may include detecting a presence of at least one error in the one or more data words.

Prior to the step of multiplying the vector of one or more data words with the parity matrix to determine the plurality of syndrome values at 342, the method may further include receiving the one or more data words. The one or more data words may be generated from signals received from memory cells of the memory device.

In various embodiments, the method may include receiving and processing each data word of the one or more data words to generate the plurality of syndrome values at at least substantially the same time.

In various embodiments, multiplying the vector of one or more data words with the parity matrix at 342 may include multiplying the vector of one or more data words with the parity matrix including elements of a Galois Field to determine the plurality of syndrome values including odd-index syndrome values.

The method may further include determining even-index syndrome values S₂ᵢ based on the odd-index syndrome values S₂ᵢ₋₁ and a property of S₂ᵢ=(sᵢ)² where i=1, . . . t, and t being an error correction capability of the decoder, in accordance with various embodiments.

The syndrome vector may further include the even-index syndrome values of S₂ᵢ where i=1, . . . t; and the syndrome matrix may further include the even-index syndrome values of S₂ᵢ where i=1, . . . t−1.

In various embodiments, generating the plurality of coefficients at 344 may include applying a Peterson-Gorenstein-Zierler (PGZ) algorithm on the plurality of syndrome values.

For example, a square syndrome value may be determined for each of the plurality of syndrome values and the plurality of coefficients may be generated based on the square syndrome values and the plurality of syndrome values.

In various embodiments, the method may further include receiving a column address of the one or more data words to determine a starting search index. The column address may be converted to the starting search index through LUTs.

In various embodiments, prior to the step of performing the Chien search on the first part of the plurality of coefficients at 346, the method may include selecting from the plurality of coefficients based on the starting search index, the first part of the plurality of coefficients.

In various embodiments, determining the first set of error indicators at 346 may include determining roots of an error locator polynomial, wherein the error locator polynomial may include the first part of the plurality of coefficients.

In various embodiments, prior to the step of performing the Chien search on the second part of the plurality of coefficients at 348, the method may include selecting from the plurality of coefficients based on the starting search index, the second part of the plurality of coefficient.

In various embodiments, determining the second set of error indicators at 348 may include determining roots of an error locator polynomial, wherein the error locator polynomial may include the second part of the plurality of coefficients.

In various embodiments, performing the Chien search at 346, 348 may include multiplying the starting search index with the first part of the plurality of coefficients or the second part of the plurality of coefficients.

In various embodiments, performing the Chien search at 346, 348 may further include storing a plurality of multiplication results of the starting search index and the first part of the plurality of coefficients, or a plurality of multiplication results of the starting search index and the second part of the plurality of coefficients. The multiplication results may be stored for a next cycle of operation.

In various embodiments, the method may further include storing the one or more data words and the plurality of coefficients.

In various embodiments, the method may further include providing a row address and a column address of memory cells of the memory device. The method may further include selecting the first part of the one or more data words or the second part of the one or more data words based on the column address.

In various embodiments, the method may further include removing at least one error from the first part of the one or more data words based on the first set of error indicators, or from the second part of the one or more data words based on the second set of error indicators. In doing so, an error-free output may be obtained.

While the method described above is illustrated and described as a series of steps or events, it will be appreciated that any ordering of such steps or events are not to be interpreted in a limiting sense. For example, some steps may occur in different orders and/or concurrently with other steps or events apart from those illustrated and/or described herein. In addition, not all illustrated steps may be required to implement one or more aspects or embodiments described herein. Also, one or more of the steps depicted herein may be carried out in one or more separate acts and/or phases.

Examples of the architecture of a Bose-Chaudhuri-Hocquenghem (BCH) decoder in accordance with various embodiments are described as follow.

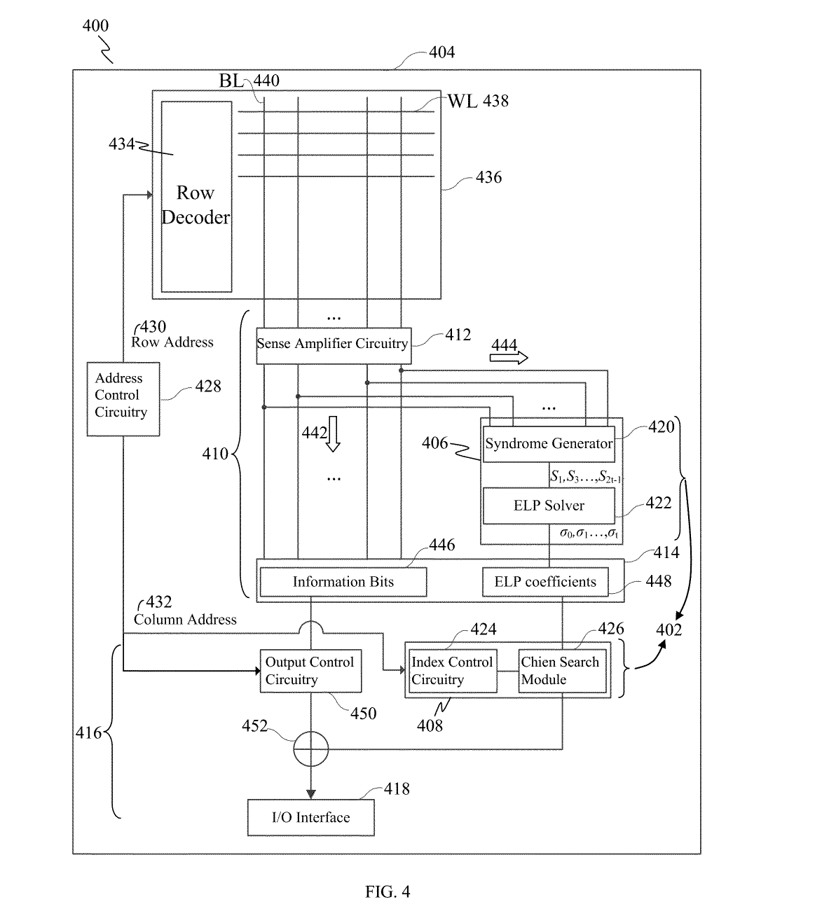

FIG. 4 shows a schematic view 400 of a BCH decoder 402 in accordance with various embodiments in a memory device 404. The BCH decoder 402 may be composed of two portions: an error detection circuitry 406 and an error correction circuitry 408.

The decoder 402 of FIG. 4 may include the same or like elements or components as those of the decoder 300 of FIG. 3A, and as such, the like elements may be as described in the context of the decoder 300 of FIG. 3A. The memory device 404 of FIG. 4 may include the same or like elements or components as those of the memory device 320 of FIG. 3B, and as such, the like elements may be as described in the context of the memory device 320 of FIG. 3B.

As seen in FIG. 4, the error detection circuitry 406 locates among the parallel data path 410 with page-size data between a sense amplifier circuitry 412 and a data register 414, while the error correction circuitry 408 locates among the serial data path 416 between the data register 414 and an I/O interface 418.

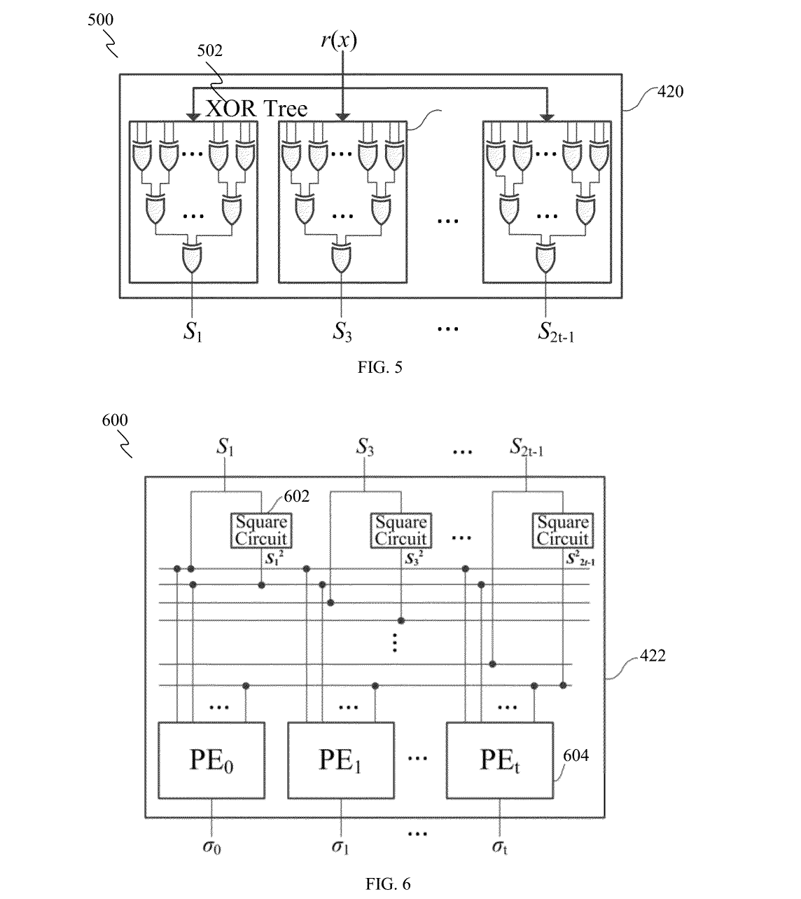

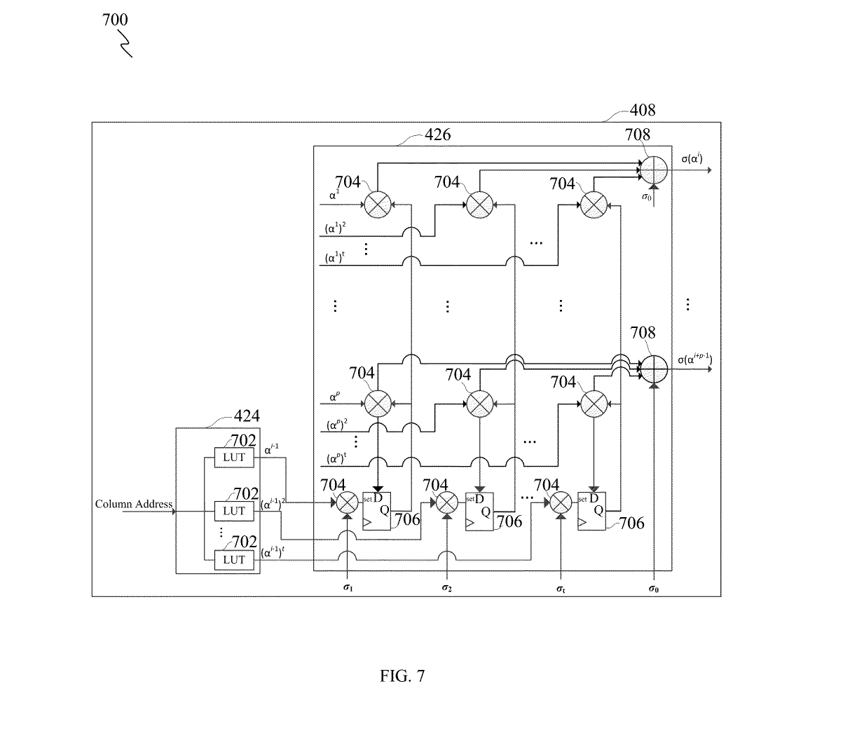

The error detection circuitry 406 may include a syndrome generator circuitry 420 (or may be simply referred to as a syndrome generator) and an error locator polynomial (ELP) solver circuitry 422 (or may be simply referred to as an ELP solver), which are described with reference to FIG. 5 and FIG. 6, respectively. The error correction circuitry 408 may include an index control circuitry 424 and a Chien search module 426 with a more detailed discussion with reference to FIG. 7.

During a memory read operation, an address control circuitry 428 may first produce a row address 430 and a column address 432 of memory cells. The row address 430 may be fed into a row decoder 434 and then a block of data with codeword length may be read out of a memory array 436. In other words, more specially, each memory cell in the memory array 436 may be coupled to a specific wordline (WL) 438 and bitline (BL) 440 that may constitute a specific cell address. All memory cells in the same WL 438 may be referred to as a page. With the row decoder 434, one WL 438 in the memory array 436 may be selected and a page of data (e.g., 32 bytes/64 bytes page size) may be read out of the memory array 436 in parallel.

The sense amplifier circuitry 412 may make a decision on the content of memory cells and may generate an according binary data (or may be referred to as one or more data words). After that, the one or more data words may be sent into two distinct paths A 442 and B 444. Through Path A 442, the information data of the codeword (e.g., the one or more data words) may be stored in an information bits register 446 of the data register 414. As mentioned above, a data parallel-to-serial conversion may exist among the memory read path. Hence, the register 446 may be needed to temporarily store the information data. In the meantime, the one or more data words may be sent to the error detection circuitry 406. The syndrome generator 420 may receive the one or more data words and may generate the syndrome vectors. The syndrome values may indicate whether there are errors in the data. All the syndromes equaling to zero may indicate that the received vector is a valid codeword, otherwise, the presence of non-zero syndromes may indicate that the received vector has errors. After the syndrome generator 420 performs the generation of syndrome vectors, the ELP solver 422 may calculate the coefficients of error location polynomial, which indicates the number of errors in the codeword. The coefficients may be calculated by using the Peterson-Gorenstein-Zierler (PGZ) algorithm and stored in an ELP coefficients register 448 of the data register 414. The error detection circuitry 406 may be implemented totally (entirely) with parallel combinational logic.

Syndromes may be computed from the received vector of one or more data words using a method to multiply the received vector with a parity matrix H as follows:

$$( {S}_{1} , {S}_{3} … , {S}_{2 t - 1} ) = ( {r}_{0 ,} {r}_{1} … , {r}_{n} ) \cdot [ \begin{matrix}1 & 1 & 1 & … & 1 \\ ( α ) & ( {α}^{3} ) & ( {α}^{5} ) & … & ( {α}^{2 t - 1} ) \\ {( α )}^{2} & {( {α}^{3} )}^{2} & {( {α}^{5} )}^{2} & … & {( {α}^{2 t - 1} )}^{2} \\ ⋮ & ⋮ & ⋮ & … & ⋮ \\ {( α )}^{n - 1} & {( {α}^{3} )}^{n - 1} & {( {α}^{2 t - 1} )}^{2} & … & {( {α}^{2 t - 1} )}^{n - 1}\end{matrix} ] \qquad Equation [ 6 ]$$

where α is the primitive element over GF(2^{m}).

All the entries in H are elements of Galois Fields expressed as power of a, which may also be represented as a binary vector.

In other words, the syndromes may be computed by the binary matrix multiplication in Equation [6].

For binary BCH code, only the odd-index syndromes may need to be computed using Equation [6] because the even-index syndromes may be obtained using the property of S₂ᵢ=(sᵢ)² where i=1, . . . t, as in Equation [4].

As mentioned above, the syndrome values may indicate whether there are errors in the received data. If all the syndromes are zero, it may be indicated that the received data is a valid codeword and no error exists, otherwise, if any one syndrome is non-zero, there are errors.

Syndrome values obtained by using Equation [6] may be the same as those obtained by using Equation [3]. However, the hardware implementation of Equations [3] and [6] may be comparatively different.

Compared to calculation of the remainder in Equation [3], implementation of Equation [6] may be more straightforward. Each element GF(2^{m}) may have an equivalent representation of m-tuple binary vector, hence the H matrix may be expressed as a simple binary matrix. Furthermore, all the element values in the matrix may be pre-determined. As a result, syndrome calculation in Equation [6] may be transformed to modulo-2 addition of the received vector of the one or more data words, that may be simply implemented by XOR combinational logic in hardware.

To obtain the coefficients of error-location polynomial, a Peterson-Gorenstein-Zierler (PGZ) algorithm may be used. In other words, the coefficients may be obtained by directly solving the PGZ equation in Equation [7]:

$$[ \begin{matrix}{S}_{t + 1} \\ {S}_{t + 2} \\ ⋮ \\ {S}_{2 t}\end{matrix} ] = [ \begin{matrix}{S}_{1} & {S}_{2} & … & {S}_{t} \\ {S}_{2} & {S}_{3} & … & {S}_{t + 1} \\ ⋮ & ⋮ & & ⋮ \\ {S}_{t} & {S}_{t + 1} & … & {S}_{2 t - 1}\end{matrix} ] [ \begin{matrix}{σ}_{t} \\ {σ}_{t - 1} \\ ⋮ \\ {σ}_{1}\end{matrix} ] \qquad Equation [ 7 ]$$

For a given t, the coefficients may be directly solved from Equation [7]. In contrast with the Berlekamp-Massey (BM) algorithm described above, the PGZ algorithm may remove the iterative process. Furthermore, all the coefficients expressions may be pre-calculated with software tools like Matlab, which may significantly facilitate the hardware implementation. When t is small (t<5), Equation [7] may not be considered as complicated, hence the solutions may be implemented with low complexity. However, when t is large (t>5), the PGZ algorithm may not be considered advantageous because the number of equations may grow rapidly and the expressions of equation solutions may become significantly complex.

The latency of the error detection circuitry 406 may be due to combinational logic propagation delays and no other delays. As a result, the full-parallel implementation of the error detection circuitry 406 may minimize memory access latency overhead.

The data register 414 may contain all the resources prepared for error correction, namely, the one or more data words in the information bits register 446 and the coefficients of ELP in the ELP coefficients register 448. Data error correction and output process may involve the address control circuitry 428, an output control circuitry 450, the index control circuitry 424, the Chien search module 426, and an addition module 452. In early address decoding phase, the address control circuit 428 may send the decoded column address 432 to the output control circuitry 450 and the index control circuitry 424. In the output control circuitry 450, the column address may act as an input index of multiplexer for data selection. In the index control circuitry 424, the column address may be used to generate the start search index for the Chien search module 426 by using a look-up table (LUT).

With command of data output, the output control circuitry 450 may select and output the according portion of data in the information bits register 446 sequentially. The number of data selected per clock cycle may be determined by the number of I/O ports, typically 8 bits to 64 bits. The Chien search circuitry 426 may be synchronously activated with the output control circuitry 450. The Chien search circuitry 426 may receive the start search index from the index control circuitry 424, and may perform a test as represented by Equation (8).

According to the Chien search algorithm, the test at the i-th location of the received vector of the one or more data words is to check whether the following equation is satisfied:

σ(α⁻ⁱ)=0 i=0,1 . . . n—1 Equation [8]

where α is the primitive element over GF(2^{m}).

If α⁻¹ is the root of error locator polynomial, then an error bit may be found at location index i. The Chien search module may carry out enumeration of the received data, that is, to perform Equation (8) from index i=0 to index i=n−1. From Equation (8), it may be observed that the mathematical operations of index i test involves multiplying the coefficients σ₁, σ₂ . . . σₜ by α⁻ⁱ, (α⁻ⁱ)² . . . (α⁻ⁱ)^{t} respectively, and the summation of the results. Circuit complexity may increase linearly with the number of index that is tested simultaneously. Therefore, it may be important to determine whether the index test is conducted in a parallel manner or in a serial manner, which may be significantly dependent on the BCH decoder application.

When the test in Equation [8] is done, the Chien search circuitry 426 may generate the error indicators of the according data locations. In various examples, the degree of parallelism of the Chien search circuitry 426, that is, the number of bits processed at each clock cycle, may be configured as the same to the number of output data from the output control circuitry 450, which may in turn be determined by the number of I/O ports. With such configuration, at each clock cycle, the raw information data from the output control circuitry 450 may at least substantially match or exactly match its according error indicators from the Chien search module 426. The errors may be removed by adding the raw data and its corresponding error indicators in the addition module 452. Finally, a valid word may be send to the I/O circuitry 418.

In another example, the Chien search circuitry 426 may be configured such that the starting search index of Chien search may be generated from the memory column address 432 with the index control circuitry 424. The degree of parallelism for the Chien search module 426 may be equal to the number of output data from the output control circuitry 450, which may, in turn, be determined by the number of memory I/O ports.

Typically, the degree of parallelism for the Chien search module 426 may be equal to number of I/O ports or double the number of I/O ports if double data rate (DDR) interface is used. The principal advantage may be that the Chien search module 426 has a much smaller area due to the limited I/O ports. In addition, the Chien search module 426 may support memory burst read operation because in the Chien search module 426, the intermediate results may be registered and the error indicators output at a next cycle may correspond to that of the next column address.

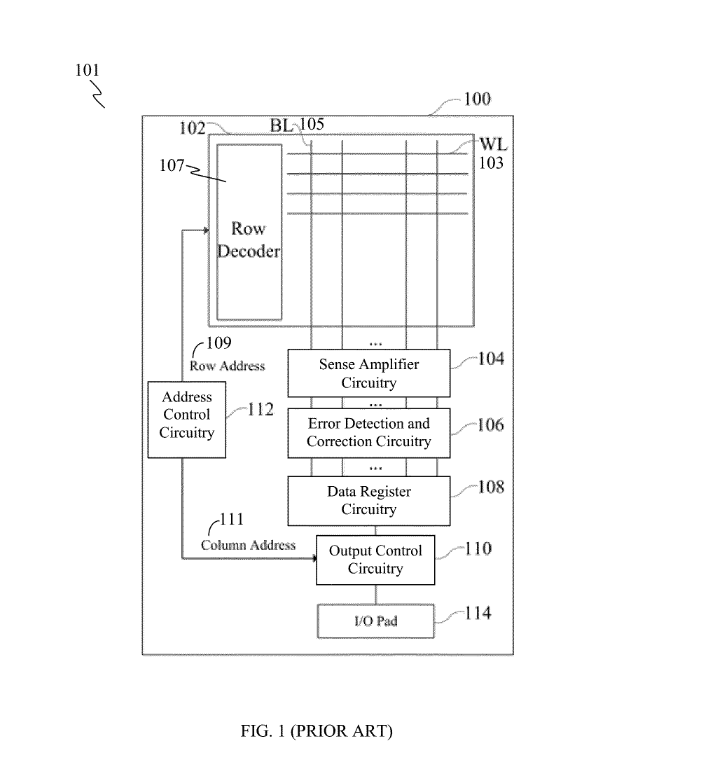

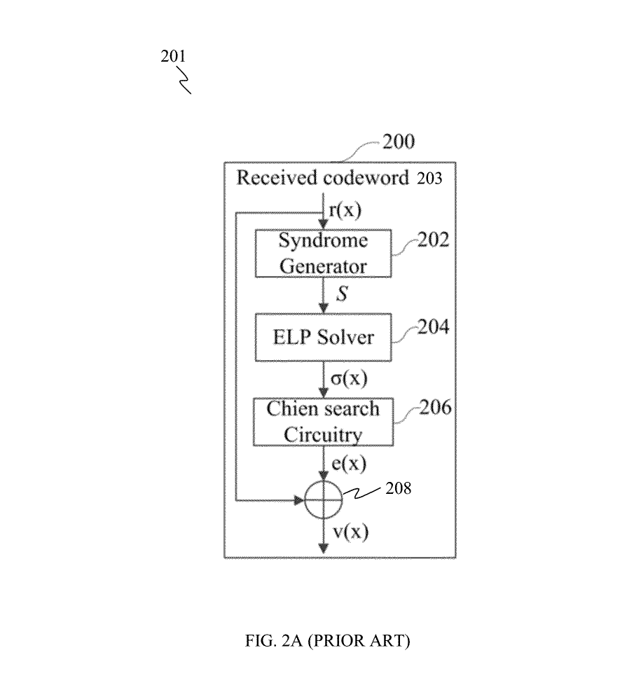

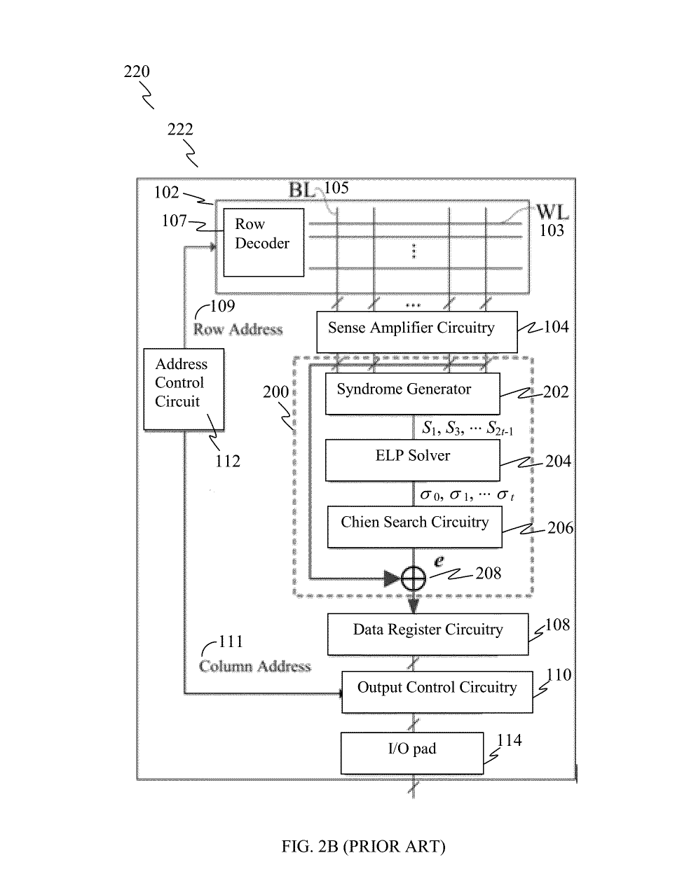

In contrast with conventional implementation, for example, as shown in FIG. 1, where the overall ECC decoder is directly inserted into the read path, the architecture design of the BCH decoder in accordance with various embodiments may fully take advantage of the memory feature where a parallel portion is associated with parallel data read from the memory array and the a portion is associated with serial data sent to the memory I/O pins. The architecture design may divide the BCH decoder into two portions, namely the error detection circuitry 406 and the error correction circuitry 408. The error detection circuitry 406 may be associated with the parallel path with page-size data while the error detection circuitry 408 may be associated with the serial path with I/O port-size data. In addition, each portion may have its specific hardware implementation. For example, the error detection circuitry 406 may be implemented in a full-parallel manner to minimize decoding latency while the error correction circuitry 408 may be designed towards a low-complexity solution.

With such an architecture, the memory read access latency overhead due to ECC may be reduced. Since the error correction circuitry 408 may be performed synchronously with data output process, its decoding latency may thus be eliminated or at least minimized. Consequently, the read access overhead may be reduced from the latency of the whole BCH decoder to that of the error detection circuitry 406. The decoder area may also be reduced due to the partial-parallel circuit structure of the Chien search module 426. As a result, both memory access latency and decoder area may be reduced.

FIG. 5 shows a schematic view 500 of an exemplary circuit structure of the syndrome generator 420 of FIG. 4. The syndromes may be calculated with the matrix multiplication in Equation [6]. The contents of the H-matrix may be elements of GF(2^{m}) that may be represented as the binary vectors, hence, the syndrome calculation may be transformed to exclusive-or operations on the received vector r(x), which may be simply implemented by a XOR-tree circuit structure, as shown in FIG. 5. The syndrome generator circuitry 420 may include parallel XOR trees 502. Since only odd-index syndromes are needed to be computed, the number of XOR trees 502 may be t rather than 2t, where t is the error correction capability of the BCH code. In a worst case scenario, the depth of the XOR tree 502 may be log₂(n), where n is the codeword. Hence, the decoding latency of the syndrome generator 420 may be log₂(n)τₓₒᵣ, where τₓₒᵣ is the latency of an XOR gate.

FIG. 6 shows a schematic block diagram 600 of an exemplary implementation of the ELP solver 422 in FIG. 4. As mentioned above, the coefficients of ELP may be obtained by directly solving the PGZ equation in Equation [7]. Furthermore, all the expressions of equation solutions may be pre-calculated with a software tool. For example, the coefficient expressions of the ELP for the BCH code with t=2, 3, 4 are enumerated in Table 1.

TABLE 1
Coefficient Expressions

| | t = 2 | t = 3 | t = 4 |
|---|---|---|---|
| σ₀ | S₁ | S₁³ + S₃ | S₁⁶ + S₁³S₃ + S₁S₅ + S₃² |
| σ₁ | S₁² | S₁S₃ + S₁⁴ | S₁⁷ + S₁⁴S₃ + S₁²S₅ + S₁S₃² |
| σ₂ | S₁³ + S₃ | S₁²S₃ + S₅ | S₁⁸ + S₁⁵S₃ + S₁S₇ + S₃S₅ |
| σ₃ | N/A | S₃² + S₁⁶ + S₁³S₃ + | S₁⁶S₃ + S₁⁴S₅ + S₁²S₇ + S₃³ |
| | | S₁S₅ | |
| σ₄ | N/A | N/A | S₁¹⁰ + S₁⁷S₃ + S₁⁵S₅ + S₁³S₇ + |
| | | | S₁²S₃ S₅ + S₁ S₃³ + S₅² + S₃S₇ |

The hardware implementation of the coefficient expressions is shown in FIG. 6. In the ELP solver 422, the square of each syndrome may be firstly calculated in a square circuit 602 because the syndrome square usually has basic or very simple algebraic expressions, which may reduce the hardware resource. An example of representations of the syndrome square in GF(2⁹) is shown in Table 2.

TABLE 2
Components of syndrome square in GF(2⁹)

| S² | Expression |
|---|---|
| S²[0] | S[0] + S[7] |
| S²[1] | S[1] |
| S²[2] | S[1] + S[8] |
| S²[3] | S[6] |
| S²[4] | S[2] + S[7] |
| S²[5] | S[5] + S[7] |
| S²[6] | S[3] + S[8] |
| S²[7] | S[6] + S[8] |
| S²[8] | S[4] |

Syndrome and square of syndrome are the basic components to implement the coefficient expressions. Operations in Table 1 involve multiplications and additions in a Galois field, which may be implemented in the process elements (PE) 604 in FIG. 6. All the PEs 604 may be realized with combinational XOR logic and AND logic. An example of the latency in terms of logic gate of the ELP solver 422 for the BCH code on GF(2⁹) with t=2, 3, 4 is listed in Table 3, where τₓₒᵣ is the latency of XOR gate and τ_{AND} is the latency of AND gate.

TABLE 3
Latency of the ELP Solver 422

| t | Latency |
|---|---|
| 2 | 7τ_{XOR} + τ_{AND} |
| 3 | 13τ_{XOR} + 2τ_{AND} |
| 4 | 20τ_{XOR} + 3τ_{AND} |

FIG. 7 shows a schematic view 700 of the error correction circuitry 408 in FIG. 4. The implementation may be carried out in a high speed of about 1 GHz virtex field-programmable gate array (FPGA). The error correction circuitry 408 may include the index control circuitry 424 and the Chien search module 426 (or may be interchangeably referred to as the Chien search circuitry). The index control circuitry 424 may include a number of look-up tables (LUTs) 702. These LUTs 702 may convert the input memory column address i to the according element αⁱ⁻¹, (αⁱ⁻¹), . . . (αⁱ⁻¹)^{t}, which may be the starting search index in the Chien search module 426. A constant multiplier 704 may multiply these elements with the coefficients of ELP in order to get the expressions of the p initial search elements, where p is the degree of parallelism. The Chien search module 426 may perform error location test of p indices in parallel and may output error indicators of p information data at each clock cycle. In the meantime, some of the multiplication results may be stored in registers 706 for the next cycle operation, so the output of the Chien search module 426 at the next cycle may correspond to the error indicators of the information data of the next column address. This may allow the Chien search module 426 to support memory burst read operation. The Chien search module 426 may include a plurality of multipliers 704, registers 706, and summation modules 708. The outputs of the multipliers 704 may be summed up at the summation module 708 to test whether σ(α⁻ⁱ)=0. If so, then an error exits at the i-th location.

In an example, read access time overhead may be reduced by more than 30%. Table 4 shows a set of comparison data of read access time overhead using ECC codeword lengths of 16 byte and 32 byte obtained from memory devices in accordance with various embodiments (e.g., implemented with Xilinx virtex-7) and a conventional memory device (e.g., as in FIG. 1).

TABLE 4

| | | |
|---|---|---|
| Conventional | Proposed | Improvement |
| device | device | (%) |

ECC codeword length: 16 Byte

| | | | |
|---|---|---|---|
| t = 2 | 5.786 ns | 3.793 ns | 34.5% |
| t = 3 | 7.283 ns | 4.918 ns | 32.5% |
| t = 4 | 10.073 ns | 6.421 ns | 36.3% |

ECC codeword length: 32 Byte

| | | | |
|---|---|---|---|
| t = 2 | 6.073 ns | 3.915 ns | 35.5% |
| t = 3 | 7.473 ns | 5.134 ns | 31.3% |
| t = 4 | 10.625 ns | 6.349 ns | 40.2% |

The decoder area for the BCH decoder in accordance with various embodiments may be significantly reduced as compared to that for a conventional decoder. For example, Table 5 shows a set of comparison results of a 16 byte BCH decoder area in accordance with various embodiments and a conventional decoder, both obtained with memory I/O pin number equal to 8, while Table 6 shows a set of comparison results of a 32 byte BCH decoder area in accordance with various embodiments, obtained with the parallel degree of Chien search equal to 8, and a conventional decoder.

TABLE 5

| | | Syndrome | Error Location | Chien | |
|---|---|---|---|---|---|
| | FPGA Slice | Generator | Polynomial | Search | |
| | LUTs | (SG) | (ELP) | (CS) | Total |
| t = 2 | Conventional | 268 | 157 | 2178 | 2603 |
| | device | | | | |
| | Proposed | 268 | 157 | 252 | 677 |
| | device | | | | |
| | Reduced | 0% | 0% | 88.4% | 74.4% |
| t = 3 | Conventional | 425 | 586 | 2266 | 3277 |
| | device | | | | |
| | Proposed | 425 | 586 | 345 | 1356 |
| | device | | | | |
| | Reduced | 0% | 0% | 84.8% | 58.6% |
| t = 4 | Conventional | 505 | 1591 | 3085 | 5181 |
| | device | | | | |
| | Proposed | 505 | 1591 | 413 | 2509 |
| | device | | | | |
| | Reduced | 0% | 0% | 86.6% | 51.6% |

TABLE 6

| | | Syndrome | Error Location | Chien | |
|---|---|---|---|---|---|
| | FPGA Slice | Generator | Polynomial | Search | |
| | LUTs | (SG) | (ELP) | (CS) | Total |
| t = 2 | Conventional | 628 | 137 | 3598 | 4363 |
| | device | | | | |
| | Proposed | 628 | 137 | 221 | 986 |
| | device | | | | |
| | Reduced | 0% | 0% | 93.9% | 77.4% |
| t = 3 | Conventional | 909 | 496 | 5282 | 6687 |
| | device | | | | |
| | Proposed | 909 | 496 | 331 | 1736 |
| | device | | | | |
| | Reduced | 0% | 0% | 93.7% | 74.0% |
| t = 4 | Conventional | 1287 | 1691 | 5870 | 8848 |
| | device | | | | |
| | Proposed | 1287 | 1691 | 437 | 3415 |
| | device | | | | |
| | Reduced | 0% | 0% | 92.6% | 61.4% |

It is observed from Tables 5 and 6 that the reduction in decoder area may be mainly contributed by the Chien search module of the BCH decoder in accordance with various embodiments.

A low-latency and area-efficient BCH decoder in accordance with various embodiments may be provided and designed specially for memory.

The BCH decoder may fully take advantage of a unique feature of memory read path, each portion of the BCH decoder being designed associated with a data flow path in the memory and having specific circuit structure. The BCH decoder may achieve comparatively better performance than conventional decoders in terms of reduction in memory access time and reduction of BCH decoder area. The BCH decoder in accordance with various embodiments may be widely used for STT-MRAM, PCM, ReRAM. The error correction capability of the BCH decoder may be less than or equal to 5. The maximum operating frequency of the Chien search engine (or module) may determine the I/O interface the decoder that may be applied. A control signal may be required to activate the index control circuitry and the Chien search engine (or interchangeably referred to as the Chien search module).

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. A decoder for a memory device, the decoder comprising:
an error detection circuitry configured to multiply a vector of one or more data words for which an error detection is to be carried out with a parity matrix to determine a plurality of syndrome values and generate a plurality of coefficients from multiplying a syndrome vector with an inverse of a syndrome matrix, wherein both the syndrome vector and the syndrome matrix comprise the plurality of syndrome values; and
an error correction circuitry configured to perform a Chien search on a first part of the plurality of coefficients to determine a first set of error indicators indicating error locations in a first part of the one or more data words, and subsequently perform a Chien search on a second part of the plurality of coefficients to determine a second set of error indicators indicating error locations in a second part of the one or more data words.

2. The decoder of claim 1, wherein the error detection circuitry is arranged along a parallel memory read path of the memory device.

3. The decoder of claim 1, wherein the error detection circuitry comprises a syndrome generator configured to multiply the vector of one or more data words with the parity matrix comprising elements of a Galois Field to determine the plurality of syndrome values comprising odd-index syndrome values.

4. The decoder of claim 3, wherein the syndrome generator is further configured to determine even-index syndrome values S₂ᵢ based on the odd-index syndrome values S₂ᵢ₋₁ and a property of S₂ᵢ=(sᵢ)² where i=1, . . . t, and t being an error correction capability of the decoder.

5. The decoder of claim 4, wherein the error detection circuitry further comprises an error locator polynomial (ELP) solver configured to generate the plurality of coefficients from multiplying the syndrome vector with the inverse of the syndrome matrix, wherein the syndrome vector further comprises the even-index syndrome values of S₂ where i=1, t; and wherein the syndrome matrix further comprises the even-index syndrome values of S₂₁ where i=1, . . . t−1.

6. The decoder of claim 3, wherein the syndrome generator comprises a plurality of logic trees, each of the plurality of logic trees configured to receive and process each data word of the one or more data words to generate the plurality of syndrome values at at least substantially the same time.

7. The decoder of claim 1, wherein the error detection circuitry comprises an error locator polynomial (ELP) solver configured to generate the plurality of coefficients by applying a Peterson-Gorenstein-Zierler (PGZ) algorithm on the plurality of syndrome values.

8. The decoder of claim 7, wherein the ELP solver comprises a plurality of square circuits, each configured to determine a square syndrome value for each of the plurality of syndrome values; and a plurality of process elements configured to generate the plurality of coefficients based on the square syndrome values and the plurality of syndrome values.

9. The decoder of claim 1, wherein the error correction circuitry is arranged along a serial memory read path of the memory device.

10. The decoder of claim 1, wherein the error correction circuitry comprises an index control circuitry configured to receive a column address of the one or more data words to determine a starting search index.

11. The decoder of claim 10, wherein the index control circuitry comprises a plurality of look-up tables configured to convert the column address to the starting search index.

12. The decoder of claim 10, wherein the error correction circuitry further comprises a Chien search module configured to select from the plurality of coefficients based on the starting search index, the first part of the plurality of coefficients, and to perform the Chien search on the first part of the plurality of coefficients.

13. The decoder of claim 12, wherein the Chien search module is configured to determine the first set of error indicators based on roots of an error locator polynomial, wherein the error locator polynomial comprises the first part of the plurality of coefficients.

14. The decoder of claim 12, wherein the Chien search module is further configured to select from the plurality of coefficients based on the starting search index, the second part of the plurality of coefficients, and to perform the Chien search on the second part of the plurality of coefficients.

15. The decoder of claim 14, wherein the Chien search module is configured to determine the second set of error indicators based on roots of an error locator polynomial, wherein the error locator polynomial comprises the second part of the plurality of coefficients.

16. The decoder of claim 12, wherein the Chien search module comprises a plurality of multipliers configured to multiple the starting search index with the first part of the plurality of coefficients or the second part of the plurality of coefficients.

17. The decode of claim 12, wherein the Chien search module has a degree of parallelism equal to or double the number of input-output (I/O) ports of the memory device.

18. A memory device comprising:
a sense amplifier circuitry configured to provide one or more data words;
a decoder comprising:
an error detection circuitry configured to multiply a vector of the one or more data words for which an error detection is to be carried out with a parity matrix to determine a plurality of syndrome values and generate a plurality of coefficients from multiplying a syndrome vector with an inverse of a syndrome matrix, wherein both the syndrome vector and the syndrome matrix comprise the plurality of syndrome values; and
an error correction circuitry configured to perform a Chien search on a first part of the plurality of coefficients to determine a first set of error indicators indicating error locations in a first part of the one or more data words, and subsequently perform a Chien search on a second part of the plurality of coefficients to determine a second set of error indicators indicating error locations in a second part of the one or more data words; and
a data register configured to store the one or more data words and the plurality of coefficients,
wherein the error detection circuitry is arranged between the sense amplifier circuitry and the data register.

19. The memory device of claim 18, further comprising an input-output (I/O) interface configured to receive or output data into or from the memory device,
wherein the error correction circuitry is arranged between the data register and the I/O interface.

20. A method of decoding a memory device, the method comprising:
multiplying a vector of one or more data words for which an error detection is to be carried out with a parity matrix to determine a plurality of syndrome values;
generating a plurality of coefficients from multiplying a syndrome vector with an inverse of a syndrome matrix, wherein both the syndrome vector and the syndrome matrix comprise the plurality of syndrome values;
performing a Chien search on a first part of the plurality of coefficients to determine a first set of error indicators indicating error locations in a first part of the one or more data words; and
subsequently performing a Chien search on a second part of the plurality of coefficients to determine a second set of error indicators indicating error locations in a second part of the one or more data words.
